(19) United States
(12) Patent Application Publication
(10) Pub. No.: US 2026/0259284 A1
(43) Pub. Date: Sep. 3, 2026

(54) PERMEABILITY SPECTRUM TESTING DEVICE AND METHOD FOR MICRON-SIZED SAMPLE BASED ON NEAR-FIELD MICROWAVE PROBE

(71) Applicant: Lanzhou University, Lanzhou City (CN)

(72) Inventors: Xiling LI, Lanzhou City (CN); Guozhi CHAI, Lanzhou City (CN); Zongyuan ZHANG, Lanzhou City (CN); Shize QIN, Lanzhou City (CN); Desheng XUE, Lanzhou City (CN); Jianbo WANG, Lanzhou City (CN)

(21) Appl. No.: 19/066,387

(22) Filed: Feb. 28, 2025

(51) Int. Cl. G01R 33/12; G01R 1/067

(52) U.S. Cl. CPC G01R 33/1223; G01R 1/06772

(57) ABSTRACT

Provided is a permeability spectrum testing device and method for a micron-sized sample based on a near-field microwave probe. The permeability spectrum testing device for a micron-sized sample based on a near-field microwave probe includes the near-field microwave probe, a vector network analyzer (VNA), and a control system that are connected sequentially, where the near-field microwave probe includes a microwave probe tip having a signal terminal and a ground terminal shorted; the near-field microwave probe is connected to the VNA to form an impedance loop; when the target sample is tested, an impedance of the impedance loop changes, followed by a change of a scattering parameter (S-parameter) of the VNA; and the VNA is configured to receive reflected signals detected by the near-field microwave probe in four states, obtain S-parameters in the four state, and determine a permeability spectrum of the target sample.

### TECHNICAL FIELD

The present disclosure relates to the field of high-frequency microwave test, and in particular to a permeability spectrum testing device and method for a micron-sized sample based on a near-field microwave probe.

### BACKGROUND

As a hotspot of research in the field of electronic information materials at present, the magnetic thin film is typically fabricated into micro-sized dot-matrix units by micromachining, and has been widely applied to various fields of electronics, including information storage, electromagnetic compatibility, magnetic sensors and microwave communication devices. Different requirements are proposed for different applications of the magnetic thin film. The complex permeability spectrum of the magnetic thin film plays an important role in practical application.

At present, the complex permeability of the thin-film material is mainly measured by the microwave resonant cavity method, the pickup coil method, the transmission/reflection method, etc. In research of high-frequency magnetic properties, measurement on the permeability of the thin film is limited by a measurement mechanism. Specifically, the sample is either placed in a microwave device or brought into direct contact with a microwave board. For example, the currently used shorted microstrip line (MSL) device includes one end shorted to the ground through brass, and the other end welded to an SMA coaxial connector. In this testing method, the magnetic thin film is pushed into the microwave transmission line fixture.

Since the size and geometrical shape of the target sample are limited by the testing device, the conventional permeability spectrum testing method cannot realize in-site test on the micron-sized sample.

### SUMMARY

In view of this, embodiments of the present disclosure provide a permeability spectrum testing device and method for a micron-sized sample based on a near-field microwave probe. The present disclosure has no limitation on the size of the target sample, and achieves a wider application scope.

To achieve the above objective, the embodiments of the present disclosure provide the following technical solutions:

A permeability spectrum testing device for a micron-sized sample based on a near-field microwave probe includes the near-field microwave probe, a vector network analyzer (VNA), and a control system, where

the near-field microwave probe includes a microwave probe tip having a signal terminal and a ground terminal shorted; the near-field microwave probe is connected to a scattering parameter (S-parameter) testing port of the VNA; the VNA is connected to the control system; the near-field microwave probe directly faces a sample testing area; and the sample testing area is configured to place a target sample;

a distance between the near-field microwave probe and the target sample is a first preset distance; the first preset distance is greater than 0 and less than 100 μm; the near-field microwave probe is configured to transmit a microwave signal between the target sample and the VNA; the near-field microwave probe is connected to the VNA to form an impedance loop; and when the impedance loop approaches to the target sample, an impedance of the impedance loop changes, followed by a change of an S-parameter of the VNA;

the VNA is configured to receive reflected signals detected by the near-field microwave probe in four states, obtain S-parameters in the four states according to the reflected signals in the four states, and send the S-parameters in the four states to the control system;

the four states include: the sample testing area is only in an unloaded state; the sample testing area is in the unloaded state with a magnetic field of a preset magnetic field intensity applied; the sample testing area only has the target sample; and the sample testing area has the target sample with a saturated magnetic field of a preset magnetic field direction applied; and

the control system is configured to determine a permeability spectrum of the target sample according to the S-parameters in the four states.

Optionally, the near-field microwave probe further includes a gold wire; and the signal terminal and the ground terminal of the microwave probe tip are shorted through the gold wire.

Optionally, a distance between the signal terminal and the ground terminal of the near-field microwave probe is 150 μm; both the signal terminal and the ground terminal of the near-field microwave probe have a diameter of 3 μm; and the gold wire has a diameter of 20 μm.

Optionally, the near-field microwave probe further includes a coaxial adapter; and

an output terminal of the near-field microwave probe is connected to the S-parameter testing port of the VNA through the coaxial adapter.

Optionally, the permeability spectrum testing device for a micron-sized sample based on a near-field microwave probe further includes a three-dimensional (3D) moving platform; and

the sample testing area is provided on the 3D moving platform; and the 3D moving platform is configured to drive the target sample on the sample testing area to move, such that the near-field microwave probe and the target sample are kept at the first preset distance.

Optionally, the permeability spectrum testing device for a micron-sized sample based on a near-field microwave probe further includes a microscope; and

the microscope is configured to observe a position of the near-field microwave probe, a position of the target sample, and the distance between the near-field microwave probe and the target sample.

Optionally, the preset magnetic field intensity is 4000 ^{Oe}; and the preset magnetic field direction is parallel to a film surface direction of the target sample.

The present disclosure further provides a permeability spectrum testing method for a micron-sized sample based on a near-field microwave probe, where the permeability spectrum testing method for a micron-sized sample based on a near-field microwave probe is realized with the permeability spectrum testing device for a micron-sized sample based on a near-field microwave probe, and the permeability spectrum testing method for a micron-sized sample based on a near-field microwave probe includes:

controlling the near-field microwave probe to directly face the sample testing area, and to keep the first preset distance away from the target sample;

when the sample testing area is only in the unloaded state, receiving, by the VNA, a reflected signal detected by the near-field microwave probe, and obtaining an S-parameter in a first state according to the reflected signal;

when the sample testing area is in the unloaded state with the magnetic field of the preset magnetic field intensity applied, receiving, by the VNA, a reflected signal detected by the near-field microwave probe, and obtaining an S-parameter in a second state according to the reflected signal;

when the sample testing area only has the target sample, receiving, by the VNA, a reflected signal detected by the near-field microwave probe, and obtaining an S-parameter in a third state according to the reflected signal;

when the sample testing area has the target sample with the saturated magnetic field of the preset magnetic field direction applied, receiving, by the VNA, a reflected signal detected by the near-field microwave probe, and obtaining an S-parameter in a fourth state according to the reflected signal; and

determining the permeability spectrum of the target sample according to the S-parameters in the four states.

Optionally, before the controlling the near-field microwave probe to directly face the sample testing area, and to keep the first preset distance away from the target sample, the permeability spectrum testing method for a micron-sized sample based on a near-field microwave probe further includes: calibrating a whole permeability spectrum testing network, specifically:

calibrating the whole permeability spectrum testing network with a microwave probe tip having a signal terminal and a ground terminal not shorted and a calibration standard, where the calibrated permeability spectrum testing network is configured to connect the near-field microwave probe to test the permeability spectrum.

According to specific embodiments provided in the present disclosure, the present disclosure has the following technical effects:

According to the embodiments of the present disclosure, the signal terminal and the ground terminal of the microwave probe tip are shorted to obtain the near-field microwave probe. The near-field microwave probe is configured to transmit the microwave signal between the target sample (as a sample end) and the VNA. The distance between the near-field microwave probe and the target sample is the first preset distance. The near-field microwave probe is connected to the VNA to form the impedance loop. When the impedance loop approaches to the target sample, the impedance of the impedance loop changes, followed by a change of the S-parameter of the VNA. The VNA obtains the S-parameter when the sample testing area is in the unloaded state, the S-parameter when the sample testing area is in the unloaded state with the magnetic field applied, the S-parameter when the sample testing area has the target sample, the S-parameter when the sample testing area has the target sample with the saturated magnetic field applied, thereby determining the permeability spectrum of the target sample. The testing device has no limitation on the size of the target sample, and achieves a wider application scope. Meanwhile, the near-field microwave probe and the target sample are kept at the first preset distance in measurement, namely the measurement can be realized without contact between the near-field microwave probe and the target sample. The non-contact state can prevent influences of dielectric properties of the target sample on the S-parameter, thereby improving the detection accuracy.

### BRIEF DESCRIPTION OF THE DRAWINGS

To describe the technical solutions in embodiments of the present disclosure or in the prior art more clearly, the accompanying drawings required in the embodiments are briefly described below. Apparently, the accompanying drawings in the following description show merely some embodiments of the present disclosure, and other drawings can still be derived from these accompanying drawings by those of ordinary skill in the art without creative efforts.

FIG. 1 is a first structural view of a permeability spectrum testing device for a micron-sized sample based on a near-field microwave probe according to an embodiment of the present disclosure;

FIG. 2 is a second structural view of a permeability spectrum testing device for a micron-sized sample based on a near-field microwave probe according to an embodiment of the present disclosure;

FIG. 3 is a perspective view of a near-field microwave probe according to an embodiment of the present disclosure;

FIG. 4 is a sectional view of a near-field microwave probe according to an embodiment of the present disclosure;

FIG. 5 is a graph of a permeability of a yttrium iron garnet (YIG) thin film tested by a near-field microwave test system as a function of a frequency according to an embodiment of the present disclosure; and

FIG. 6 is a graph of a permeability of a YIG thin film tested by a shorted MSL test system as a function of a frequency according to an embodiment of the present disclosure.

### REFERENCE NUMERALS

1: gold wire, 2: coaxial adapter, 3 : 3D moving platform, 4: microscope, 5: target sample, S: signal terminal, and g: ground terminal.

### DETAILED DESCRIPTION OF THE EMBODIMENTS

The technical solutions in the embodiments of the present disclosure will be described below in combination with the accompanying drawings in the embodiments of the present disclosure.

An objective of the present disclosure is to provide a permeability spectrum testing device and method for a micron-sized sample based on a near-field microwave probe. A signal terminal S and a ground terminal G of a microwave probe tip are shorted to form the near-field microwave probe. The near-field microwave probe is configured to transmit a microwave signal between a target sample and a VNA. The VNA is configured to receive a reflected signal detected by the near-field microwave probe, thereby obtaining S-parameters to determine a permeability spectrum of the target sample. The present disclosure has no limitation on the size of the target sample, and achieves a wider application scope.

In order to make the above objective, features and advantages of the present disclosure clearer and more comprehensible, the present disclosure will be further described in detail below in combination with accompanying drawings and specific implementations.

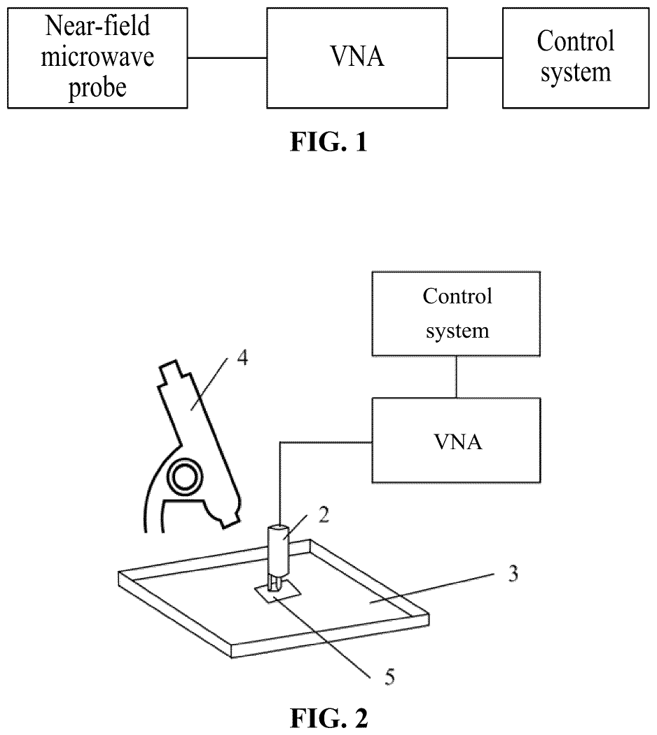

Referring to FIG. 1 and FIG. 2, an embodiment provides a permeability spectrum testing device for a micron-sized sample based on a near-field microwave probe, including the near-field microwave probe, a VNA, and a control system that are connected sequentially.

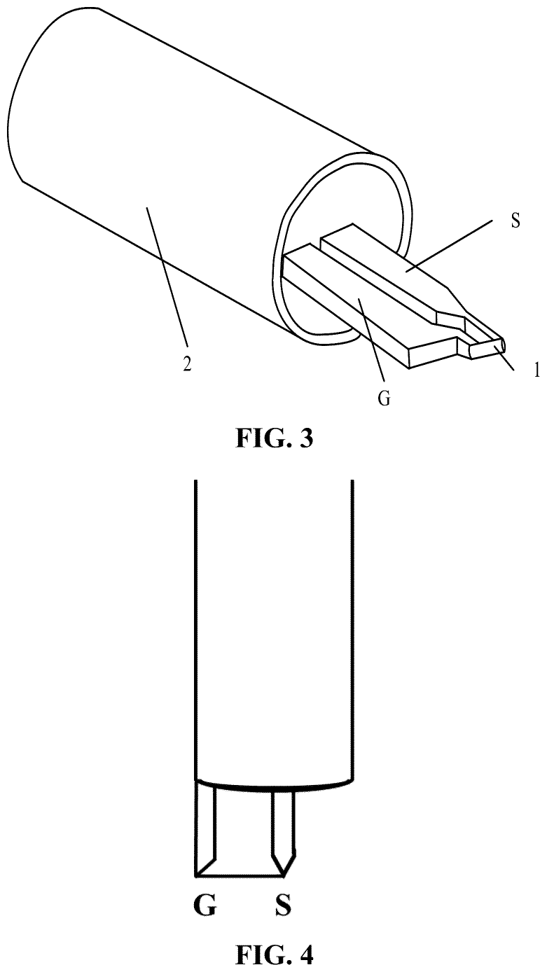

Referring to FIG. 3 and FIG. 4, the near-field microwave probe includes a microwave probe tip having a signal terminal S and a ground terminal G shorted. An output terminal of the near-field microwave probe is connected to an S-parameter testing port (such as an S₁₁ port) of the VNA. The VNA is connected to the control system. The near-field microwave probe directly faces a sample testing area. The sample testing area is configured to place a target sample 5. The target sample 5 may be a thin-film sample. The parameter tested by the S₁₁ port is an S₁₁ parameter.

A distance between the near-field microwave probe and the target sample 5 is a first preset distance. The near-field microwave probe is configured to transmit a microwave signal between the target sample and the VNA. The near-field microwave probe is connected to the VNA to form an impedance loop. When the impedance loop approaches to the target sample 5, an impedance of the impedance loop changes, followed by a change of an S-parameter of the VNA. The first preset distance is greater than 0 and less than 100 μm to ensure a highly accurate test result.

The VNA is configured to receive reflected signals detected by the near-field microwave probe in four states, obtain S-parameters in the four states according to the reflected signals in the four states, and send the S-parameters in the four states to the control system. The S-parameter is amplitude of the S₁₁ parameter.

The four states include: The sample testing area is only in an unloaded state. The sample testing area is in the unloaded state with a magnetic field of a preset magnetic field intensity applied. The sample testing area only has the target sample 5. The sample testing area has the target sample 5 with a saturated magnetic field of a preset magnetic field direction applied. The preset magnetic field intensity may be 4000 ^{Oe} (the magnetic field intensity depends on specific conditions in the test). The preset magnetic field direction is parallel to a film direction of the target sample 5. The preset magnetic field intensity is far greater than a magnetic field intensity of the saturated magnetic field of the target sample 5.

The control system is configured to determine a permeability spectrum of the target sample 5 according to the S-parameters in the four states.

In an example, the near-field microwave probe further includes a gold wire 1. The signal terminal S and the ground terminal G of the near-field microwave probe are shorted through the gold wire 1. Specifically, tips of the signal terminal S and the ground terminal G of the microwave probe tip are welded with the gold wire 1.

A distance between the signal terminal S and the ground terminal G of the near-field microwave probe may be 150 μm. Both the signal terminal S and the ground terminal G of the microwave probe tip may have a diameter of 3 μm. The gold wire 1 may have a diameter of 20 μm. The probe head of a micron scale is used in the example, so the test accuracy is higher, and the resolution can reach the micron scale.

In an example, referring still to FIG. 3 and FIG. 4, the near-field microwave probe further includes a coaxial adapter 2. The output terminal of the near-field microwave probe is connected to the S-parameter testing port of the VNA through the coaxial adapter 2.

Specifically, the output terminal of the near-field microwave probe is connected to one end of the 2.92 mm coaxial adapter 2 by fine welding. Then, the whole component is fixed on a probe holder. The other end of the coaxial adapter 2 is connected to the S-parameter testing port of the VNA through a coaxial cable.

In an example, the permeability spectrum testing device for a micron-sized sample based on a near-field microwave probe further includes a 3D moving platform 3. The sample testing area is provided on the 3D moving platform 3. The 3D moving platform 3 is configured to drive the target sample 5 on the sample testing area to move, such that the near-field microwave probe and the target sample 5 are kept at the first preset distance.

In an example, the permeability spectrum testing device for a micron-sized sample based on a near-field microwave probe further includes a microscope 4. The microscope 4 is configured to observe a position of the near-field microwave probe, a position of the target sample 5, and the distance between the near-field microwave probe and the target sample 5. The microscope 4 may be an electron microscope.

In an example, in order to reduce the experimental error, the whole permeability spectrum testing device for a micron-sized sample based on a near-field microwave probe is provided on an anti-vibration table to reduce influences of environmental vibration on microwave transmission.

The permeability spectrum testing device for a micron-sized sample based on a near-field microwave probe in the example has no limitation on the size or geometrical shape of the sample and can even measure the micron-sized micrographic sample or properties of the magnetic material integrated into different areas in the chip, and thus can realize high frequency measurement on various materials in actual operating conditions.

In actual application, the permeability spectrum testing device for a micron-sized sample based on a near-field microwave probe is implemented as follows: The target sample 5 is placed below the microscope 4. The target sample 5 is placed on the 3D moving platform 3 which is movable in the X axis, the Y axis, and the Z axis. The target sample 5 is adjusted through the 3D moving platform 3, until the target sample 5 is appropriately located in a center of a field of view (FoV) of the microscope 4. By observing the FoV of the microscope 4, the near-field microwave probe is moved to the FoV of the microscope 4 and above the target sample 5. While the FoV of the microscope 4 is observed, the near-field microwave probe is moved down slowly above the sample testing area of the target sample 5, such that the near-field microwave probe approaches gradually to the target sample 5. Whether the near-field microwave probe and the target sample contact can be known through the microscope 4 and a signal displayed on the VNA. When the near-field microwave probe and the target sample contact, whether the sample is contacted is observed in the microscope 4, and the signal on the VNA changes abruptly. A distance in a Z-axis direction is controlled through the 3D moving platform 3, until the target sample 5 and the near-field microwave probe are kept at the first preset distance (such as 50 μm), namely the target sample and the near-field microwave probe approach to each other without contact. The non-contact state prevents influences of dielectric properties of the sample on the S₁₁ parameter. By this time, the sample is placed below the near-field microwave probe. Compared with the impedance loop formed in the unloaded state, the impedance changes, and the corresponding S₁₁ parameter also changes. The S₁₁ parameter when the sample testing area is in the unloaded state, the S₁₁ parameter when the sample testing area is in the unloaded state with the magnetic field applied, the S₁₁ parameter when the sample testing area has the target sample 5, and the S₁₁ parameter when the sample testing area has the target sample 5 with the saturated magnetic field applied are acquired. With the four S₁₁ parameters, the permeability spectra of the target sample 5 in different microscopic areas can be obtained.

According to the transmission theory of an electromagnetic wave in the transmission line, a relation among the S₁₁ parameter of the VNA, the effective dielectric constant and the permeability can be obtained. By deducting the dielectric constant, the permeability can be obtained. That is, the permeability is obtained by calculating the S₁₁ parameters of the VNA in different steps. First of all, in the unloaded state of the near-field microwave test system, namely only the near-field microwave probe is connected to the VNA, and the target sample 5 is not provided below the near-field microwave probe, the S₁₁ parameter of the whole system is acquired. Then, in the unloaded state, a large direct-current (DC) field (generally having a magnetic field intensity of greater than 4000 ^{Oe}) is applied, and the S₁₁ parameter of the whole test system is acquired. Next, the sample is placed below the near-field microwave probe, and approaches to the near-field microwave probe without contact. Both the effective magnetic permeability and the dielectric constant have changed, and the S₁₁ parameter is acquired. At last, for the purpose of eliminating influences from the dielectric constant of the substrate, in a direction parallel to an easy axis of the thin film, a magnetic field H (which is the same as the field in the second step in direction and magnitude) with a magnetic field intensity greater than the magnetic field intensity of the saturated magnetic field of the thin film is applied. The permeability spectrum can be deduced through the four S₁₁ parameters.

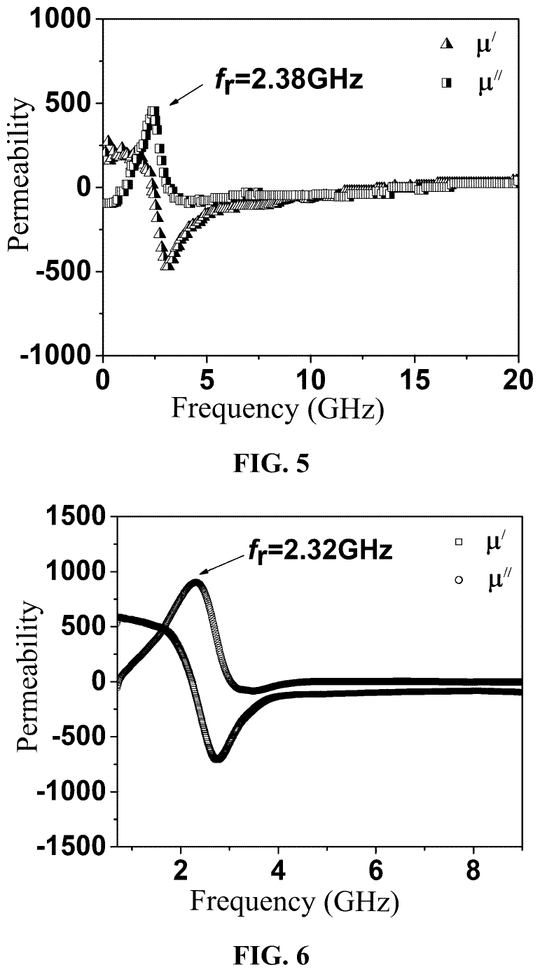

FIG. 5 illustrates a high-frequency permeability spectrum of a 100 μm*100 μm YIG thin film tested by the permeability spectrum testing device for a micron-sized sample based on a near-field microwave probe. In the figure, the resonance frequency fᵣ is 2.38 GHz, and the test result is consistent with the result of the shorted MSL test on the continuous YIG thin film in FIG. 6. The frequency tested by the shorted MSL method is 2.32 GHz, so the error is 2.5%. The test frequency of the whole test system can be up to 20 GHz. The very small micron-sized sample cannot be tested by the common shorted MSL method, but the testing device can test the high-frequency magnetic properties of the microscope sample or the microscope area of the sample.

It is to be noted that before the near-field microwave probe is moved, the existing microwave probe tip (the non-shorted microwave probe) is processed to obtain the near-field microwave probe. Specifically, for the microwave probe tip of the near-field microwave probe, the 40A-GS-150-DP produced by the GGB is used, the signal terminal S and the ground terminal G are kept at 150 μm, and the gold wire 1 having the diameter of 20 μm is welded to the tip of the signal terminal S and the tip of the ground terminal G by the fine welding (micron-scale welding), such that the signal terminal S and the ground terminal G are connected. Then, the near-field microwave probe is connected to the coaxial adapter 2 by the fine welding, and both the near-field microwave probe and the coaxial adapter are fixed on the probe holder. The coaxial adapter 2 is connected to the VNA. The VNA is connected to the control system (such as the computer). The near-field microwave probe approaches to the target sample 5 infinitely. The target sample 5 is placed on the programmed 3D moving platform 3. The test process of the near-field microwave probe and the target sample 5 is observed through the microscope 4.

The permeability spectrum testing device for a micron-sized sample based on a near-field microwave probe uses the near-field microwave probe, and its test principle is the same as the test principle of the near field scanning microwave microscope (NSMM). The NSMM is processed on the coaxial cable, and its test accuracy can only be millimeter-scale. The present disclosure is realized based on the micron-scale near-field microwave probe, and thus has the higher test accuracy and the micron-scale resolution.

The permeability spectrum testing device for a micron-sized sample based on a near-field microwave probe mainly achieves the following advantages: (1) The target sample 5 does not contact the probe. (1) There is no limitation on the size of the sample. (3) The testing method can test the microscopic sample (micron-scale) or the microscopic area of the sample to realize the micro-area scanning resolution. (4) Compared with the conventional testing method using the shorted MSL fixture, the test frequency can be improved to 20 GHz from 9 GHz. (5) Compared with the conventional testing method using the shorted MSL fixture, the test accuracy is higher. (6) The whole test process is convenient, efficient, and easy-to-operate.

The present disclosure further provides a permeability spectrum testing method for a micron-sized sample based on a near-field microwave probe. The permeability spectrum testing method for a micron-sized sample based on a near-field microwave probe is realized with the permeability spectrum testing device for a micron-sized sample based on a near-field microwave probe. The permeability spectrum testing method for a micron-sized sample based on a near-field microwave probe includes the following steps:
(1) A whole test system is calibrated in an open-short-load (OSL) manner with a microwave probe tip (namely the common microwave probe tip) having a signal terminal S and a ground terminal G not shorted and a commercial calibration standard. The signal terminal S and the ground terminal G of the common microwave probe tip are not connected.

The common microwave probe tip is a radio-frequency (RF) microwave probe tip, and may be the 40A-GS-150-DP provided by the GGB.
(2) The near-field microwave probe is connected to the calibrated testing network to test the subsequent permeability spectrum. Specifically, the tips of the signal terminal S and the ground terminal G of the common microwave probe tip are welded with the micron-scale gold wire 1 to obtain the near-field microwave probe.
(3) The near-field microwave probe is controlled to directly face the sample testing area, and to keep the first preset distance away from the target sample 5.
(4) When the sample testing area is only in the unloaded state, the VNA receives a reflected signal detected by the near-field microwave probe, and obtains an S-parameter in a first state according to the reflected signal.
(5) When the sample testing area is in the unloaded state with the magnetic field of the preset magnetic field intensity applied, the VNA receives a reflected signal detected by the near-field microwave probe, and obtains an S-parameter in a second state according to the reflected signal.
(6) When the sample testing area only has the target sample 5, the VNA receives a reflected signal detected by the near-field microwave probe, and obtains an S-parameter in a third state according to the reflected signal.
(7) When the sample testing area has the target sample 5 with the saturated magnetic field of the preset magnetic field direction applied, the VNA receives a reflected signal detected by the near-field microwave probe, and obtains an S-parameter in a fourth state according to the reflected signal.
(8) The permeability spectrum of the target sample 5 is determined according to the S-parameters in the four states.

The novel method for testing the permeability spectrum of the magnetic material provided by the present disclosure is very important to characterize magnetization dynamic properties of the magnetic material.

Each embodiment in the description is described in a progressive mode, each embodiment focuses on differences from other embodiments, and references can be made to each other for the same and similar parts between embodiments. Since the method disclosed in the embodiment corresponds to the device disclosed in the embodiment, the description is relatively simple. For relevant information, reference can be made to the description of the device.

Particular examples are used herein for illustration of principles and implementation modes of the present disclosure. The descriptions of the above embodiments are merely used for assisting in understanding the method of the present disclosure and its core ideas. In addition, those of ordinary skill in the art can make various modifications in terms of particular implementation modes and the scope of application in accordance with the ideas of the present disclosure. In conclusion, the content of the description shall not be construed as limitations to the present disclosure.

What is claimed is:

1. A permeability spectrum testing device for a micron-sized sample based on a near-field microwave probe, comprising the near-field microwave probe, a vector network analyzer (VNA), and a control system, wherein
the near-field microwave probe comprises a microwave probe tip having a signal terminal and a ground terminal shorted; the near-field microwave probe is connected to a scattering parameter (S-parameter) testing port of the VNA; the VNA is connected to the control system; the near-field microwave probe directly faces a sample testing area; and the sample testing area is configured to place a target sample;
a distance between the near-field microwave probe and the target sample is a first preset distance; the first preset distance is greater than 0 and less than 100 μm; the near-field microwave probe is configured to transmit a microwave signal between the target sample and the VNA; the near-field microwave probe is connected to the VNA to form an impedance loop; and when the impedance loop approaches to the target sample, an impedance of the impedance loop changes, followed by a change of an S-parameter of the VNA;
the VNA is configured to receive reflected signals detected by the near-field microwave probe in four states, obtain S-parameters in the four states according to the reflected signals in the four states, and send the S-parameters in the four states to the control system;
the four states comprises: the sample testing area is only in an unloaded state; the sample testing area is in the unloaded state with a magnetic field of a preset magnetic field intensity applied; the sample testing area only has the target sample; and the sample testing area has the target sample with a saturated magnetic field of a preset magnetic field direction applied;
the control system is configured to determine a permeability spectrum of the target sample according to the S-parameters in the four states; and
the permeability spectrum testing device for a micron-sized sample based on a near-field microwave probe is capable of testing the micron-sized sample or a microscopic area of a sample, thereby realizing a micro-area scanning resolution; and the permeability spectrum testing device for a micron-sized sample based on a near-field microwave probe has a test frequency of 20 GHz.

2. The permeability spectrum testing device for a micron-sized sample based on a near-field microwave probe according to claim 1, wherein the near-field microwave probe further comprises a gold wire; and the signal terminal and the ground terminal of the microwave probe tip are shorted through the gold wire.

3. The permeability spectrum testing device for a micron-sized sample based on a near-field microwave probe according to claim 2, wherein a distance between the signal terminal and the ground terminal of the near-field microwave probe is 150 μm; both the signal terminal and the ground terminal of the near-field microwave probe have a diameter of 3 μm; and the gold wire has a diameter of 20 μm.

4. The permeability spectrum testing device for a micron-sized sample based on a near-field microwave probe according to claim 1, wherein the near-field microwave probe further comprises a coaxial adapter; and
an output terminal of the near-field microwave probe is connected to the S-parameter testing port of the VNA through the coaxial adapter.

5. The permeability spectrum testing device for a micron-sized sample based on a near-field microwave probe according to claim 1, further comprising a three-dimensional (3D) moving platform, wherein
the sample testing area is provided on the 3D moving platform; and the 3D moving platform is configured to drive the target sample on the sample testing area to move, such that the near-field microwave probe and the target sample are kept at the first preset distance.

6. The permeability spectrum testing device for a micron-sized sample based on a near-field microwave probe according to claim 5, further comprising a microscope, wherein
the microscope is configured to observe a position of the near-field microwave probe, a position of the target sample, and the distance between the near-field microwave probe and the target sample.

7. The permeability spectrum testing device for a micron-sized sample based on a near-field microwave probe according to claim 1, wherein the preset magnetic field intensity is 4000 ^{Oe}; and the preset magnetic field direction is parallel to a film direction of the target sample.

8. A permeability spectrum testing method for a micron-sized sample based on a near-field microwave probe, wherein the permeability spectrum testing method for a micron-sized sample based on a near-field microwave probe is realized with the permeability spectrum testing device for a micron-sized sample based on a near-field microwave probe according to claim 1, and the permeability spectrum testing method for a micron-sized sample based on a near-field microwave probe comprises:
controlling the near-field microwave probe to directly face the sample testing area, and to keep the first preset distance away from the target sample, wherein the first preset distance is greater than 0 and less than 100 μm;
when the sample testing area is only in the unloaded state, receiving, by the vector network analyzer (VNA), a reflected signal detected by the near-field microwave probe, and obtaining a scattering parameter (S-parameter) in a first state according to the reflected signal;
when the sample testing area is in the unloaded state with the magnetic field of the preset magnetic field intensity applied, receiving, by the VNA, a reflected signal detected by the near-field microwave probe, and obtaining an S-parameter in a second state according to the reflected signal;
when the sample testing area only has the target sample, receiving, by the VNA, a reflected signal detected by the near-field microwave probe, and obtaining an S-parameter in a third state according to the reflected signal;
when the sample testing area has the target sample with the saturated magnetic field of the preset magnetic field direction applied, receiving, by the VNA, a reflected signal detected by the near-field microwave probe, and obtaining an S-parameter in a fourth state according to the reflected signal; and
determining the permeability spectrum of the target sample according to the S-parameters in the four states.

9. The permeability spectrum testing method for a micron-sized sample based on a near-field microwave probe according to claim 8, before the controlling the near-field microwave probe to directly face the sample testing area, and to keep the first preset distance away from the target sample, further comprising: calibrating a whole permeability spectrum testing network, specifically:
calibrating the whole permeability spectrum testing network with a microwave probe tip having a signal terminal and a ground terminal not shorted and a calibration standard, wherein the calibrated permeability spectrum testing network is configured to connect the near-field microwave probe to test the permeability spectrum.

10. The permeability spectrum testing method for a micron-sized sample based on a near-field microwave probe according to claim 8, wherein the near-field microwave probe further comprises a gold wire; and the signal terminal and the ground terminal of the microwave probe tip are shorted through the gold wire.

11. The permeability spectrum testing method for a micron-sized sample based on a near-field microwave probe according to claim 10, wherein a distance between the signal terminal and the ground terminal of the near-field microwave probe is 150 μm; both the signal terminal and the ground terminal of the near-field microwave probe have a diameter of 3 μm; and the gold wire has a diameter of 20 μm.

12. The permeability spectrum testing method for a micron-sized sample based on a near-field microwave probe according to claim 8, wherein the near-field microwave probe further comprises a coaxial adapter; and
an output terminal of the near-field microwave probe is connected to the S-parameter testing port of the VNA through the coaxial adapter.

13. The permeability spectrum testing method for a micron-sized sample based on a near-field microwave probe according to claim 8, further comprising a three-dimensional (3D) moving platform, wherein
the sample testing area is provided on the 3D moving platform; and the 3D moving platform is configured to drive the target sample on the sample testing area to move, such that the near-field microwave probe and the target sample are kept at the first preset distance.

14. The permeability spectrum testing method for a micron-sized sample based on a near-field microwave probe according to claim 13, further comprising a microscope, wherein
the microscope is configured to observe a position of the near-field microwave probe, a position of the target sample, and the distance between the near-field microwave probe and the target sample.

15. The permeability spectrum testing method for a micron-sized sample based on a near-field microwave probe according to claim 8, wherein the preset magnetic field intensity is 4000 ^{Oe}; and the preset magnetic field direction is parallel to a film direction of the target sample.
